(19) United States
(12) Patent Application Publication
(10) Pub. No.: US 2019/0356159 A1
(43) Pub. Date: Nov. 21, 2019

(54) RACK-MOUNTED UPS DEVICE FOR DATA CENTERS

(71) Applicant: ABB Schweiz AG, Baden (CH)

(72) Inventors: Antonio Coccia, Baden (CH); Esa-Kai Paatero, Helsinki (FI)

(21) Appl. No.: 16/404,127

(22) Filed: May 6, 2019

Related U.S. Application Data
(63) Continuation of application No. PCT/EP2017/078440, filed on Nov. 7, 2017.

(30) Foreign Application Priority Data
Nov. 7, 2016 (EP) 16197592.5

(51) Int. Cl. H02J 9/06; H05K 7/14; H02M 7/00

(52) U.S. Cl. CPC H02J 9/061; H02M 7/003; H05K 7/1492

(57) ABSTRACT

The present application provides a rack-mounted UPS device for power supply of a load including multiple data processing devices, which can be inserted as load enclosures into a common UPS rack, the rack-mounted UPS device including at least one primary converter, which is connected between an AC source and a high voltage DC bus, whereby the primary converter is configured to operate in boost mode providing high voltage DC power output to the high voltage DC bus, at least one secondary converter, which is connected between a DC source and the high voltage DC bus, whereby the secondary converter is configured to operate in boost mode providing high voltage DC power output to the high voltage DC bus, at least one load supply converter, which is connected between the high voltage DC bus and an internal power distribution bus to provide at least one low level DC output voltage to the internal power distribution bus, whereby the at least one primary converter, the at least one secondary converter, and the at least one load supply converter are mounted in the UPS rack, and the UPS rack includes multiple insertion slots for receiving the load enclosures comprising the data processing devices.

### TECHNICAL FIELD

The present invention relates to the area of uninterrupted power supplies, in particular for the use in data centers to provide uninterrupted power to data processing devices. In particular, the present invention relates to a UPS device for power supply of a load comprising multiple data processing devices, which can be inserted as enclosures into a common UPS rack. The present invention also provides a UPS system for power supply of a load comprising multiple data processing devices, comprising multiple UPS devices as specified above.

### BACKGROUND ART

Data centers with data processing devices and infrastructures, e.g. servers, computers, and others, are presently built around 230/400V AC energy sources and intermediate links. This is based on a historic development of data centers using standard computer hardware and standard uninterruptible power supplies (UPS). However, data centers are now well established all over the world and convert into a mature industry.

Due to overall unreliability of public AC network, data centers are typically equipped with UPS to support loads during AC source interruptions. This technology has been initially tailored to support legacy AC inputs for the data center loads, thus involves multiple serial conversion steps all introducing a cumulative efficiency penalty.

Data processing device as particular load of data centers typically use multiple voltages of the order of 48V DC down to approximately 5V or 3.3V DC or even less. The 48V DC are e.g. used for cooling purposes, e.g. a fan, whereas lower voltage like 5V or 3.3V are e.g. used to power a processor of the data processing device.

Hence, state of the Art uninterrupted power supply (UPS) systems generally comprise e.g. a central system level hardware for connecting the UPS system to a power distribution, for which uninterrupted operation has to be achieved. Hence, the system level hardware may comprise customer cable landings, bypasses, switch gears, system user interfaces and so on.

Typically, the UPS system further comprises at least one, usually multiple converters, also referred to as uninterrupted power supply modules, which store electrical power to provide it via the I/O connection enclosure to the power distribution. Number, size and power rating of the converters are chosen depending on the UPS system design based on customer requirements. UPS power systems with a power of at least 100 kW are common.

The converters are typically arranged in UPS-rack, which are connected in parallel for providing power of at least tens of kilowatt. Accordingly, the converters can be provided in the enclosures side by side to each other, which enables formation of high power UPS systems. Also parallel connection of single converters through hard wired cabling to a common I/O enclosure is known.

Such a standard UPS system 10 is shown in FIG. 1. Hence, the UPS system 10 comprises a UPS-rack 12, which contains one or multiple converters 14. By way of example, FIG. 1 shows a single converter 14. The converter 14 comprises an AC/DC converter 16, a DC/AC converter 18, and a DC/DC converter 20. The AC/DC converter 16, also referred to as rectifier, is connected at its AC side to an AC source 22. At its DC side, the AC/DC converter 16 is connected to a DC link 24. The DC/AC converter 18, also referred to as inverter, is connected at its DC side to the DC link 24. At its AC side, the DC/AC converter 18 is connected to an AC power distribution bus 26. Hence, the converters 14 implement double conversion UPS devices. Further components like bypass switches or others can be provided, but are not shown in FIG. 1.

The DC/DC converter 20 is connected between the DC link 24 and a battery 28. The battery is housed in a battery cabinet 30. The battery 28 can comprise any number of individual cells, which are connected in series and/or in parallel within the battery cabinet 30. The battery cabinet 30 may also comprise multiple batteries 28 for individually powering multiple converters 14. Hence, secure or backed-up AC power can be provided by the converter 14 to the AC power distribution bus 26, i.e. either from the AC source 22 via the AC/DC converter 16 and the DC/AC converter 18, or from the battery 28 via the DC/DC converter 20 and the DC/AC converter 18.

The UPS system 10 further comprises a control device 32, which controls the operation of the converters 14 and all other components. This control includes providing power to the AC power distribution bus 26 as well as charging the battery 28 when discharged.

The UPS system 10 powers a load 34, which is distributed over several load racks 36. The load racks 36 are connected to the AC power distribution bus 26. The load 34 comprises multiple enclosures 38, which are connected in parallel to the AC power distribution bus 26. The enclosures 38 can be provided individually or in groups in the load racks 36.

As can be further seen in FIG. 2, each enclosure 38 comprises at least one load device 40, which is in general a data processing device. However, a single enclosure 38 can comprise more than one load device 42. Each enclosure 38 further comprises at least one power supply unit 42, also referred to as PSU. The PSU 42 comprises an AC/DC converter 44, which is at its AC side connected to the AC power distribution bus 26. The AC/DC converter 44 is typically provided as boost converter. The PSU 42 further comprises a DC/DC converter 46, which receives DC power from the DC side of the AC/DC converter 44, and which provides typically different DC voltage levels to the load device 40. The DC/DC converter 46 is typically provided as buck converter. Hence, each enclosure 38 has an individual PSU 42.

As can be further seen in FIG. 3, the UPS system 10 may comprise multiple converters 14, which are connected in parallel between the AC source 22 and the AC power distribution bus 26. The converters 14 can be provided as discussed with respect to the embodiment of FIG. 1 each in a UPS rack 12. However, the same principles refer to a parallel design of multiple converters 14 within a single UPS rack 12.

As can be seen in FIG. 3, a control device 32 is provided within each UPS rack 12. The control devices 32 of the different UPS racks 12 are connected by a system communication bus 48.

System level preference is for massively parallel configurations for both power sourcing and usage to increase overall reliability and flexibility. However, state of the Art UPS systems for data centers with multiple data processing devices comprise an end-to-end system efficiency, which covers losses in all power conversion steps. Each power conversion steps adds particular losses, thereby decreasing overall end-to-end system efficiency.

Furthermore, the overall power transmission chain from the AC source to the load comprises multiple converters, thereby increasing system complexity. System failures in different converters can lead to a failure of the UPS.

In this context, document EP 2 333 930 A2 describes a server and uninterruptable power supply housed in that server. The main server block houses uninterruptible power supplies that supply 150V-400V DC operating power to the main server block input power supply lines both with and without power outage. An uninterruptible power supply has rechargeable batteries having a voltage specification of 60V or less, an AC/DC converter that converts power input from an external commercial power source to DC and supplies it to the input power supply lines, a DC/DC step-down converter that steps-down the AC/DC converter output voltage to the rechargeable battery charging voltage, a DC/DC boost converter that steps up the rechargeable battery voltage and supplies it to the input power supply lines during power outage, and a charging and discharging control circuit that detects commercial power source outage and switches the DC/DC boost converter to the operating state.

Document WO 2015/157999 A1 describes a system and methods for distributed uninterruptable power supplies. A distributed uninterruptible power supply (UPS) for mounting in a data center rack is provided. The distributed power system includes an input constructed to receive alternating current (AC) input power, an AC bus coupled to the input, a DC bus constructed to couple to at least one DC load in the data center rack, a battery bus coupled to at least one battery, and at least one power module. The at least one power module has a first input coupled to the AC bus, a second input coupled to the battery bus, and an output coupled to the DC bus and is constructed to generate DC power based on received power from at least one of the AC bus and the battery bus.

EP 1 355 404 A1 describes a DC backup power supply system having a battery; a charge-discharge circuit for charging and discharging a power between the battery and a DC line; and a control circuit for controlling the charge/discharge circuit. The battery has a number of battery cells and cylindrical portions of the battery cells are laid on an approximately horizontal plane.

### DISCLOSURE OF INVENTION

It is an object of the present invention to provide a UPS device for power supply of a load comprising multiple data processing devices, which can be inserted as enclosures into a common UPS rack, and a UPS system for power supply of a load comprising multiple data processing devices, comprising multiple UPS devices as specified above, which have an improved end-to-end system efficiency, which have a simple hardware design, which is easily scalable and simple to maintain.

This object is achieved by the independent claims. Advantageous embodiments are given in the dependent claims.

In particular, the present invention provides a rack-mounted UPS device for power supply of a load comprising multiple data processing devices, which can be inserted as enclosures into a common UPS rack, the rack-mounted UPS device further comprising at least one primary converter, which is connected between an AC source and a high voltage DC bus, whereby the primary converter is configured to operate in boost mode providing high voltage DC power output to the high voltage DC bus, at least one secondary converter, which is connected between a DC source and the high voltage DC bus, whereby the secondary converter is configured to operate in boost mode providing high voltage DC power output to the high voltage DC bus, at least one load supply converter, which is connected between the high voltage DC bus and an internal power distribution bus to provide at least one low level DC output voltage to the internal power distribution bus, whereby the at least one primary converter, the at least one secondary converter, and the at least one load supply converter are mounted in the UPS rack, the UPS rack comprises multiple insertion slots for receiving the enclosures comprising the data processing devices, and the internal power distribution bus is provided for distribution of the load voltages between the enclosures.

The present invention also provides a rack-mounted UPS system for power supply of a load comprising multiple data processing devices, comprising multiple rack-mounted UPS devices as specified above, wherein the rack-mounted UPS system comprises an inter-rack communication bus for commonly controlling the at least one primary converter, the at least one secondary converter, and the at least one load supply converter of the multiple rack-mounted UPS devices.

The basic idea of the invention is to eliminate unnecessary conversion steps between the AC source and the load while providing reliably uninterrupted power to the load. This is achieved by providing the converters locally in the UPS racks. With the above rack-mounted UPS device, an integration of functions of UPS and power supply unit can be achieved. In this context, apparently the primary converter refers to an AC/DC converter, the secondary converter refers to a DC/DC converter, and the load supply converter also refers to a DC/DC converter.

The conversion is further optimized with the high voltage DC power provided internally to the high voltage DC bus. The high voltage DC bus enables to operate the primary AC/DC converter in boost mode, which is a very efficient mode of operation when performing power conversion. Also the secondary DC/DC converter can be operated in boost mode, when the load is powered from the DC source, so that also in an operation mode when power is provided from the DC source efficient operation of the rack-mounted UPS-device is achieved. The rack-mounted UPS device and system is compatible with power supplies of the rack mounted load, e.g. data processing devices including computers, servers, or other load units. With the rack-mounted UPS device, a gain in efficiency and overall reliability can be achieved based on reduced complexity and component count.

Furthermore, reliability and accepted and normative performance for e.g. utility harmonics will result in an optimal system for end-to-end efficiency and cost through life. The rack-mounted system is capable of parallel operation under various levels of redundancy, capacity and user configuration and interaction. System configuration for specific load considerations is simple through standardized enclosures and an interconnect architecture.

The UPS rack can be any kind device providing insertion slots for insertion of the enclosures. The insertion slots may have a predefined height or merely be defined by a support for receiving an enclosure.

The high voltage DC power output refers to a power output of typically more than 200V, more typically of more than 300V.

The low level DC output voltages nominally being below 100V. Typically, the low level DC output voltage is a voltage of less than 50 V. In common data processing devices, typically multiple different voltages of the order of 48V DC down to approximately 5V or 3.3V DC or even less are used. The 48V DC are e.g. used for cooling purposes, e.g. a fan, whereas lower voltage like 5V or 3.3V are e.g. used to power a processor of the data processing device.

In case of multiple primary AC/DC converters, the primary AC/DC converters can be connected to a common AC source. Alternatively, the primary AC/DC converters can be connected to multiple AC sources. Also subsets of primary AC/DC converters can be connected to the same AC source.

In case of multiple secondary DC/DC converters, the secondary DC/DC converters can be connected to a common DC source. Alternatively, the secondary DC/DC converters can be connected to multiple DC sources. Also subsets of secondary DC/DC converters can be connected to the same DC source.

The internal power distribution bus is provided for distribution of the load voltages between the enclosures to enable facilitated system setup. Furthermore, the internal power distribution bus may further comprise a bus connection for AC source voltage and/or DC source voltage, or others.

The at least one load supply converter is provided to supply at least one low level DC output voltage to the UPS rack and the data processing devices. However, a single load supply converter can provide different low level DC output voltages as required.

The inter-rack communication bus of the rack-mounted UPS system enables commonly controlling the at least one primary converter, the at least one secondary converter, and the at least one load supply converter of the multiple rack-mounted UPS devices. Hence, the rack-mounted UPS system comprises a control device, which performs the control of the converters. The control performed by the control device is typically a supervisory control, where the rack-mounted UPS devices and/or converters thereof comprise additional control units for performing an individual control based on the supervisory control of the control device. Hence, the inter-rack communication bus maintains system control and enables usage e.g. of a user interface, which can be connected to the inter-rack communication bus.

According to a modified embodiment of the invention the load supply converter is provided as a converter block comprising multiple converter units, each of which providing at least one low level DC output voltage to the internal power distribution bus. The multiple converter units can provide different voltage levels and/or identical voltage levels to increase maximum current of the rack-mounted UPS device. However, in an alternative embodiment, a single load supply converter can provide multiple low level DC output voltages to power the load.

According to a modified embodiment of the invention the DC source is provided separate from the UPS rack, preferably in a separate room, e.g. in a battery room. The battery room can be a battery cabinet or others. Hence, security aspects can be reliably considered when locating the DC source separate from the UPS rack. Also a high freedom in choice and arrangement of the DC source can be established. Alternatively, the battery can be mounted within the UPS-rack.

According to a modified embodiment of the DC source comprises at least one energy storage device, in particular a battery, e.g. lead acid battery, a VRLA battery, or others, or ultracapacitors. Energy storage devices are typically provided as bidirectional energy storages devices, which are charged from the high voltage DC bus via the secondary converter, i.e. the DC/DC converter, and which are discharged in the opposite direction providing energy to the high voltage DC bus. The energy storages device can comprise any number of individual storage cells, e.g. battery cells, which are connected in series and/or in parallel. In some cases, energy storage devices are chosen based on response times. Ultracapacitors typically have a very fast response time on a millisecond scale, whereas lead acid batteries have a response time on a scale of tens of milliseconds.

According to a modified embodiment of the DC source comprises at least one uni-directional source out of a photovoltaic source, a fuel cell, or a rotary or inertia generator, e.g. a wind mill, a turbine, a fly wheel, or others. The uni-directional sources are provided to merely provide power via the secondary converter to the high voltage DC bus. The listed uni-directional sources are typically referred to as regenerative energy sources. However, the above list of uni-directional sources is not to be considered as limiting. Also other uni-directional sources, in particular non-regenerative energy sources, can be comprised. The uni-directional sources can further be operated as permanent power supply, which power the high voltage DC bus upon availability of power from these sources, e.g. in the case of the photovoltaic source the presence of sun, or in the case of the wind mill the presence of wind. Fuel cells typically have a response time on a scale of tens of seconds.

According to a modified embodiment of the DC source comprises multiple energy storage devices and/or uni-directional sources, and the rack-mounted UPS device comprises multiple secondary converters, whereby the multiple secondary converters are connected in parallel between the multiple energy storage units and the high voltage DC bus. Hence, a high freedom in choice of DC power can be provided. In particular, multiple different energy/storage technologies can be provided and operated in parallel and/or in series according to availability.

Overall, the Rack-mounted UPS device enables a good choice of available DC sources, which can be chosen based on response time in case of a failure of the AC source, a cost/kWh, short and long term availability, e.g. ‘day’, ‘hour’, ‘contractual commitment’ or a diurnal cycle in the case of photovoltaic sources, a dynamic performance, e.g. a load step response, capacity of a stored or alternate energy sources, or a carbon or other environmental foot print.

According to a modified embodiment of the invention the at least one primary converter, the at least one secondary converter, and the at least one load supply converter are arranged at least partially in at least one converter enclosure for insertion into a slot of the UPS rack, whereby the at least one primary converter, the at least one secondary converter, and the at least one load supply converter are electrically interconnected through the internal power distribution bus. Hence, the converters can be provided commonly within a single enclosure. This enables simple replacement of the converters as a converter enclosure. Also scalability of the rack-mounted UPS device can be achieved. The primary converter, the secondary converter, and the at least one load supply converter are arranged at least partially in at least one enclosure for insertion into a slot of the UPS rack. The converter enclosure can contain different combinations of converters, i.e. primary converters, secondary converters, and/or load supply converters. E.g. primary and secondary converters can be provided separately in converter enclosures.

According to a modified embodiment of the invention one primary converter, one secondary converter, and one load supply converter are mounted in a common converter enclosure, which is mounted in the UPS rack. Hence, each converter enclosure provides a full set of converters required to power the load. This facilitates replacement and scalability based on varying power demands of the load. The high voltage DC bus can be provided internally within the converter enclosure.

According to a modified embodiment of the invention the at least one primary converter and the at least one secondary converter are arranged in at least one enclosure for insertion into a slot of the UPS rack, and the at least one load supply converter is arranged in at least one enclosure for insertion into an insertion slot of the UPS rack, whereby the enclosures are electrically interconnected through the internal power distribution bus. Hence, primary and secondary converter, which power the high voltage DC bus, are separated from the load supply converter, which receives high voltage DC power from the high voltage DC bus. The high voltage DC bus extends through the UPS rack.

According to a modified embodiment of the invention the internal power distribution bus includes multiple parallel bus connections for at least one voltage level, and the multiple parallel bus connections for one voltage level are electrically connected with at least one bus interconnection. Hence, adaptation to different load requirements, in particular in respect to power and current, can be easily achieved.

According to a modified embodiment of the invention at least one of the at least one primary converter, the at least one secondary converter, and the at least one load supply converter has an electrical interface for connection to the internal power distribution bus with at least one out of a set of standard electrical configurations. The interface refers to an arrangement of connectors to connect the internal power distribution bus. This provides a kind of coding for the converters and the internal power distribution bus. Accordingly, different voltage levels can be provided easily throughout the UPS rack without an individual installation. Furthermore, a selection of load voltage and load current can be achieved by choice of converters to be inserted with the enclosure into the UPS rack.

According to a modified embodiment of the invention, the at least one primary converter, the at least one secondary converter, and the at least one load supply converter are provided with clip connectors to clip on the internal power distribution bus. Preferably, the internal power distribution bus is provided with bus bars, which facilitate the use of clip connectors to electrically connect the internal power distribution bus.

According to a modified embodiment of the invention the rack-mounted UPS device comprises at least one control unit controlling operation of the at least one primary converter, the at least one secondary converter, and the at least one load supply converter. The control unit can be a central control unit, which is provided independently from the converters in the UPS rack. However, also enclosure with converters can have a control unit for controlling the respective converters. In this case, one of the control units can perform an overall control of the converters of the UPS rack.

According to a modified embodiment of the invention the rack-mounted UPS device comprises a user interface for interaction of the at least one control unit controlling operation of the at least one primary converter, the at least one secondary converter, and at the at least one load supply converter. The user interface is preferably a bi-directional interface, which enables display of information of the rack-mounted UPS device and/or its components, and which enables a configuration of the rack-mounted UPS device and/or its components. In an alternative embodiment, the rack-mounted UPS system comprises the user interface, which is connected to the inter-rack communication bus.

According to a modified embodiment of the invention the power distribution bus comprises parallel vertical bus bars running through the UPS rack to allow electrical connection of an enclosure at any insertion slot. The vertical bus bars enable a simple connection of different converters and data processing devices to different voltage levels throughout the entire height of the UPS rack. Hence, the parallel vertical bus bars preferably extend through the entire height of the UPS rack. The bus bars are preferably mounted in a rear part of the UPS rack.

The enclosure positions may be all identical through height of rack or be distributed in functional sets of converter or load types.

According to a modified embodiment of the invention the converters are provided as hot swap converters. Hence, the converters do not require tool intervention for connection/disconnection to the internal power distribution bus.

According to a modified embodiment of the invention the multiple rack-mounted UPS devices are connected electrically in parallel by an external power distribution bus. The external power distribution bus can provide one or multiple voltages to the parallel UPS racks. Hence, the external power distribution bus can provide e.g. all load voltages or a subset thereof to the parallel UPS racks. Preferably, the external power distribution bus provides AC source voltages and DC source voltages to the parallel UPS racks.

According to a modified embodiment of the invention the rack-mounted UPS system comprises multiple protection and/or disconnect devices, which connect the multiple rack-mounted UPS devices to the external power distribution bus. The protection and/or disconnect devices are preferably provided in an individual enclosure for each UPS rack. Further preferred, the protection and/or disconnect devices comprise source and load protection.

According to a modified embodiment of the invention, the rack-mounted UPS system comprises a control device for commonly controlling the at least one primary converter, the at least one secondary converter, and the at least one load supply converter of the multiple rack-mounted UPS devices. However, in addition, each rack-mounted UPS device can have additional control units for controlling operation of the converters.

According to a modified embodiment of the invention, the control device is connected to the protection and disconnect devices for monitoring and control purposes. This includes preferably monitoring at least one value out of system voltages, system currents, power conditions status indications, thermal status indications, and device status indications.

According to a modified embodiment of the invention the load supply converter comprises an AC or high voltage DC output. Loads typically comprise data processing devices, so that the low level DC output voltage outputs directly at load level for the UPS functionality. However, a real installation typically contains auxiliary equipment in the UPS rack or apart from the UPS racks, which run off legacy AC or single step AC/HV DC conversion. This auxiliary equipment may comprise parts of a cooling system, alarm circuitry, building automation and others. Hence, also this auxiliary equipment benefits from an uninterruptible supply of power.

According to a modified embodiment of the invention the at least one load supply converter has a galvanic load isolation from the high voltage DC bus. The galvanic isolation eliminates direct conduction paths between the load and the high voltage DC bus. It increases system safety for the rack-mounted UPS device as well as for the rack-mounted UPS system.

### BRIEF DESCRIPTION OF DRAWINGS

These and other aspects of the invention will be apparent from and elucidated with reference to the embodiments described hereinafter.

In the drawings:

FIG. 1 shows a schematic view of a rack-mounted UPS system comprising a UPS device according to the state of the Art,

FIG. 2 shows a schematic view of a power supply unit used with the UPS system of FIG. 1 according to the state of the Art,

FIG. 3 shows a schematic view of another UPS system comprising a UPS device according to the state of the Art,

FIG. 4 shows a schematic view of a rack-mounted UPS system comprising multiple parallel rack-mounted UPS devices according to a first, preferred embodiment,

FIG. 5 shows a schematic view of a rack-mounted UPS system comprising multiple parallel rack-mounted UPS devices, which are connected via an external power distribution bus, according to a second embodiment,

FIG. 6 shows a schematic rear view of a rack-mounted UPS system comprising multiple parallel rack-mounted UPS devices with an internal power distribution bus comprising multiple bus bars according to a third embodiment,

FIG. 7 shows a schematic view of a rack-mounted UPS device according to a fourth embodiment,

FIG. 8 shows a schematic view of a rack-mounted UPS device with multiple enclosures containing a primary, a secondary and a load supply converter according to a fifth embodiment,

FIG. 9 shows a schematic view of a rack-mounted UPS device with multiple enclosures containing a primary and a secondary converter and with multiple enclosures containing a load supply converter according to a sixth embodiment,

FIG. 10 shows a schematic view of a plug for connection of a converter or an enclosure to an internal power distribution bus comprising multiple electric pins according to a seventh embodiment, and

FIG. 11 shows a schematic view of a plug connection established between a converter or an enclosure and an internal power distribution bus comprising multiple electric pins according to an eighth embodiment.

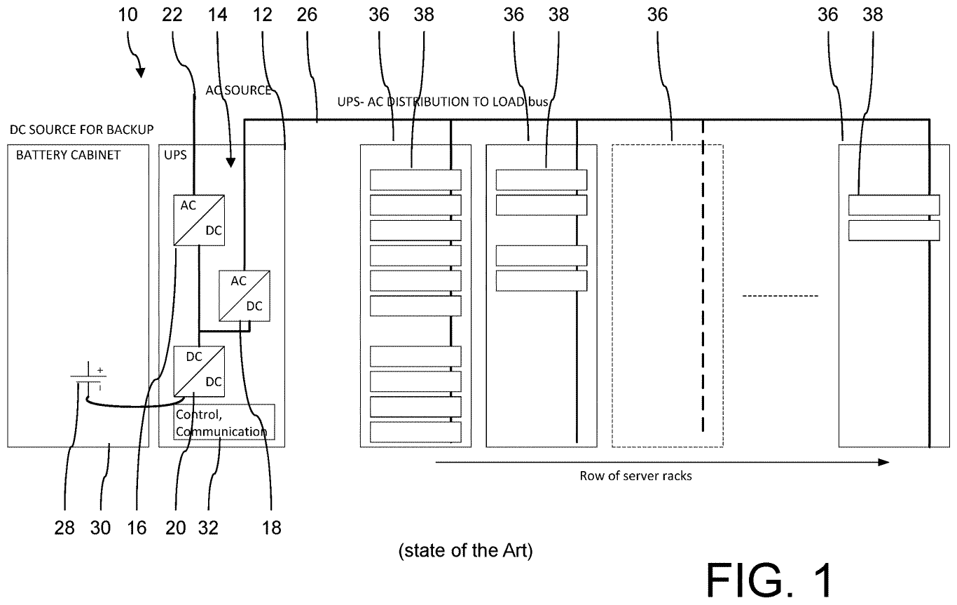

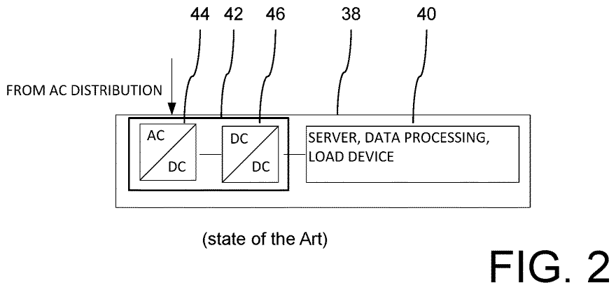

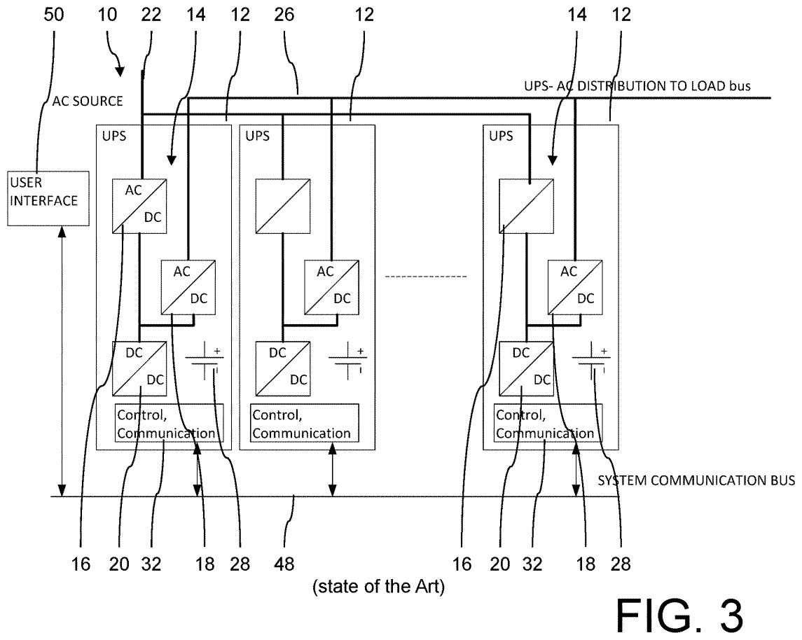

### DETAILED DESCRIPTION OF THE INVENTION

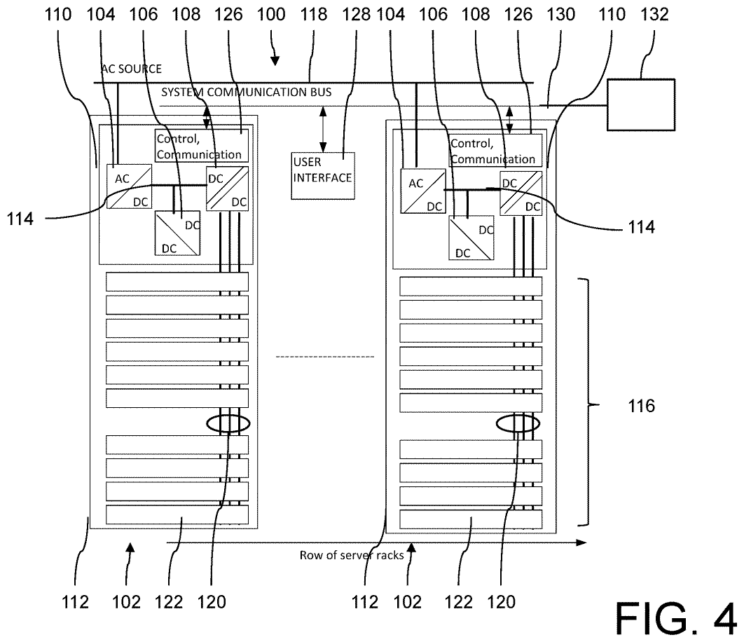

FIG. 4 shows a rack-mounted UPS system 100 according to a first, preferred embodiment. The rack-mounted UPS system 100 comprises two single rack-mounted UPS devices 102. The two rack-mounted UPS devices 102 are depicted merely by way of example. Any suitable number of rack-mounted UPS devices 102 can be used.

Each of the two rack-mounted UPS devices 102 comprises one primary converter 104, one secondary converter 106, and one load supply converter 108. The primary converter 104 refers to an AC/DC converter, the secondary converter 106 refers to a DC/DC converter, and the load supply converter 108 refers to a DC/DC converter. According to the first embodiment, the load supply converter 108 is galvanically isolated.

The primary converter 104, the secondary converter 106, and the load supply converter 108 are arranged in one converter enclosure 110 for insertion into a slot of a UPS rack 112. The primary converter 104, the secondary converter 106, and the load supply converter 108 are electrically interconnected through a high voltage DC bus 114 provided within the converter enclosure 110. The high voltage DC bus 114 has a voltage of more than 200V in this embodiment. In an alternative embodiment, the high voltage DC bus 114 has a voltage of more than 300V. The primary converter 104 and the secondary converter 106 are both configured to operate in boost mode providing high voltage DC power output to the high voltage DC bus 114.

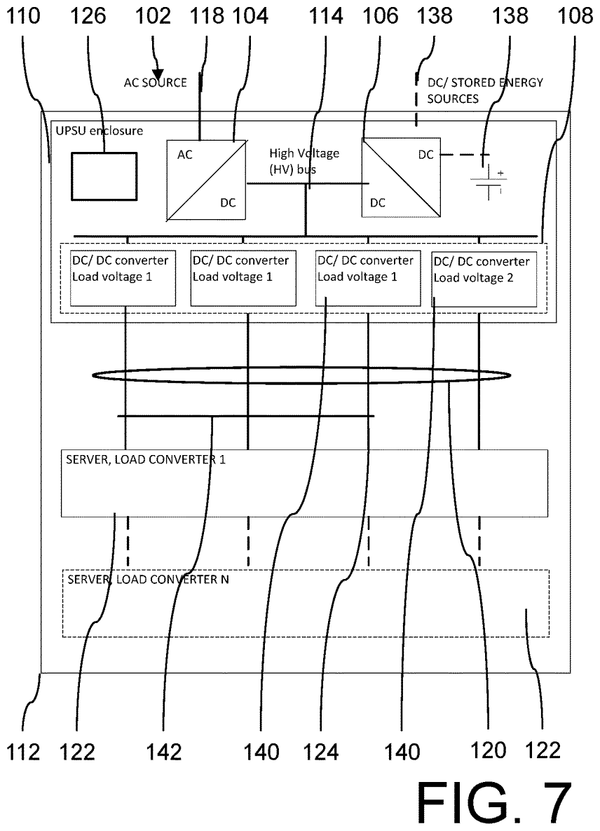

The converter enclosure 110 is electrically connected to an AC source 118. In particular, the primary converter 104 of the converter enclosure 110 is electrically connected to the AC source 118. In an alternative embodiment, the primary converters 104 are connected to multiple AC sources 118. The secondary converter 106 is connected to a DC source 138, as discussed later in detail with respect to the rack-mounted UPS devices 102 of the fourth to six embodiment with respect to FIGS. 7 to 9.

Each of the two rack-mounted UPS devices 102 comprises an internal power distribution bus 120. The internal power distribution bus 120 is connected to the load supply converter 108, which provides different low level DC output voltages to the internal power distribution bus 120. The low level DC output voltages comprise in this embodiment voltages of less than 50 V. In particular, the low level voltages comprise 48V DC, which are e.g. used for cooling purposes, e.g. a fan, and lower voltages like 5V or 3.3V used to power a processor of the data processing device.

The internal power distribution bus 120 distributes the low level DC output voltages within the rack-mounted UPS device 102. The power distribution bus 120 comprises parallel vertical bus bars 124 running through the UPS rack 112 to allow electrical connection of an enclosure 110, 122 at any insertion slot. The vertical bus bars 124 extend through the entire height of the UPS rack 112. The bus bars 124 provided in a rear part of the UPS rack 112. The enclosures 110, 122 are provided with clip connectors to electrically connect the bus bars 124 of the internal power distribution bus 120. Furthermore, the converters 104, 106, 108 are provided as hot swap converters, so that the converters 104, 106, 108 do not require tool intervention for connection/disconnection to the internal power distribution bus 120. The converters 104, 106, 108 can be easily removed with the converter enclosure 110. Furthermore, the converters 104, 106, 108 can be removed from the converter enclosure 110 without tool intervention for connection/disconnection.

According to the first embodiment, the internal power distribution bus 120 further comprises a bus bar 124 for AC source voltage.

The rack-mounted UPS device 102 further comprises multiple load enclosures 122 containing data processing devices. The load enclosures 122 are mounted in the UPS rack 112. The load enclosures 122 can comprise further converters. The load enclosures 122 provided in the rack-mounted UPS system 100 commonly form a load 128 powered by the converters 104, 106, 108 of the respective rack-mounted UPS device 102.

Each rack-mounted UPS device 102 comprises a control unit 126 controlling operation of the primary converter 104, the secondary converter 106, and the load supply converter 108. The control unit 126 can be a central control unit, which is provided independently from the converters 104, 106, 108 in the UPS rack 112. However, also converter enclosures 110 comprising one or more converters 104, 106, 108 can comprise the control unit 126 for controlling the respective converters 104, 106, 108. In this case, one of the control units 126 can perform an overall control, e.g. a supervisory control, of the converters 104, 106, 108 of the UPS rack 112.

The rack-mounted UPS system 100 further comprises a user interface 128 for interaction of the control units 126 controlling operation of the primary converter 104, the secondary converter 106, and the load supply converter 108. The user interface 128 is a bi-directional interface, which enables display of information of the rack-mounted UPS device 102 and its components, and which enables a configuration of the rack-mounted UPS device 102 and its components. The user interface 128 is connected to the rack-mounted UPS devices 102 via inter-rack communication bus 130.

The rack-mounted UPS system 100 further comprises a control device 132 for commonly controlling the primary converters 104, the secondary converters 106, and the load supply converters 108 of the multiple rack-mounted UPS devices 102. The control device 132 performs a supervisory control of the control units 126 of the rack-mounted UPS devices 102. The control device 132 is connected to the inter-rack communication bus 130.

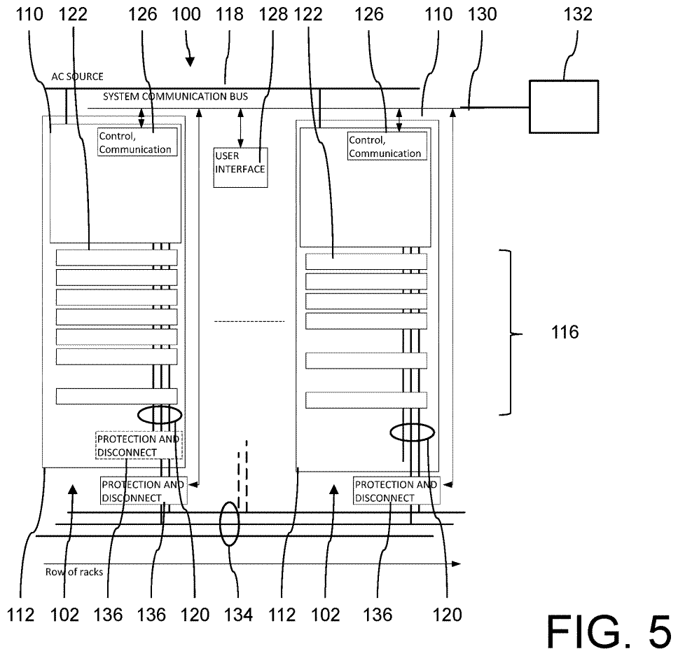

FIG. 5 shows a rack-mounted UPS system 100 according to a second embodiment. Also the rack-mounted UPS system 100 of the second embodiment is shown with two single rack-mounted UPS devices 102. However, the two rack-mounted UPS devices 102 are depicted merely by way of example. Any suitable number of rack-mounted UPS devices 102 can be combined, as indicated in FIG. 5.

The rack-mounted UPS system 100 according to a second embodiment is similar to the rack-mounted UPS system 100 of the first embodiment. Hence, only differences between the rack-mounted UPS system 100 of the first and second embodiments will be discussed in detail. Features of the second embodiment, which are not discussed in detail, correspond to the respective features of the first embodiment.

Each of the two rack-mounted UPS devices 102 comprises a converter enclosure 110 for insertion into a slot of a UPS rack 112 as discussed with respect to the first embodiment. Each of the converter enclosures 110 is electrically connected to a common AC source 118.

Each of the two rack-mounted UPS devices 102 comprises an internal power distribution bus 120 connected to the load supply converter 108, which provides different low level DC output voltages to the internal power distribution bus 120. The internal power distribution bus 120 distributes the low level DC output voltages within the rack-mounted UPS device 102. Details of the power distribution bus 120 are as described above with respect to the first embodiment.

The rack-mounted UPS devices 102 further comprise a load 116 with multiple load enclosures 122 containing data processing devices, which are mounted in the UPS rack 112.

Each rack-mounted UPS device 102 comprises a control unit 126 as discussed above with respect to the first embodiment. The rack-mounted UPS system 100 further comprises a user interface 128 and a control device 132 as discussed above with respect to the first embodiment. The user interface 128 and the control device 132 are connected to inter-rack communication bus 130.

In addition to the rack-mounted UPS system 100 of the first embodiment, the rack-mounted UPS system 100 of the second embodiment comprises an external power distribution bus 134. The external power distribution bus 134 electrically connects the multiple rack-mounted UPS devices 102 in parallel. The external power distribution bus 124 provide multiple voltages to the parallel UPS racks 112, i.e. the external power distribution bus 124 provides in this embodiment all load voltages to the parallel UPS racks 112. Hence, the voltages internal to each UPS rack 112 are routed to the adjacent UPS racks 112 for increased reliability and redundancy.

The rack-mounted UPS system 100 further comprises protection and/or disconnect devices 136, which connect the rack-mounted UPS devices 102 to the external power distribution bus 134. The protection and/or disconnect devices 136 comprise source and load protection. According to the second embodiment, the protection and/or disconnect devices 136 are provided individually from the rack-mounted UPS devices 102. However, as indicated by the protection and/or disconnect device 136 with the dashes lines, in an alternative embodiment, the protection and/or disconnect device 136 is provided in an individual protection enclosure for each UPS rack 112 as part of a respective rack-mounted UPS devices 102.

According to the second embodiment, the control device 132 is connected to the protection and disconnect devices 136 for monitoring and control purposes. This includes monitoring at least one value out of system voltages, system currents, power conditions status indications, thermal status indications, and device status indications.

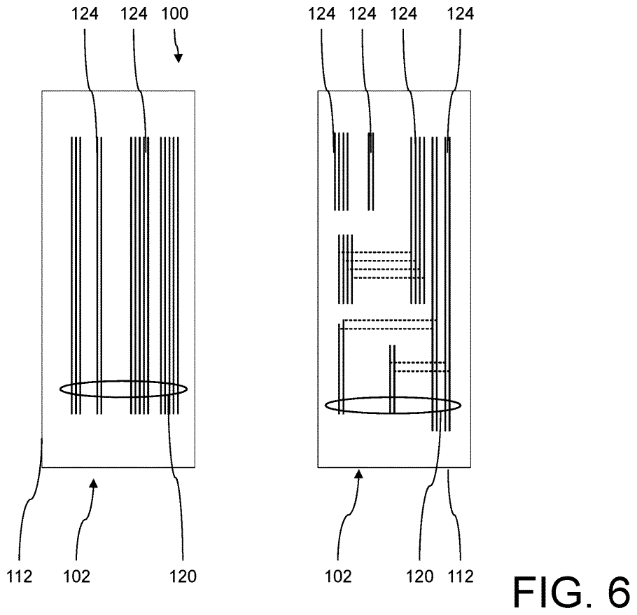

FIG. 6 refers to a rack-mounted UPS system 100 according to a third embodiment. Also the rack-mounted UPS system 100 of the third embodiment is shown with two single rack-mounted UPS devices 102. However, the two rack-mounted UPS devices 102 are depicted merely by way of example. Any suitable number of rack-mounted UPS devices 102 can be combined, as indicated in FIG. 6.

The rack-mounted UPS system 100 according to the third embodiment is similar to the rack-mounted UPS systems 100 of the first and second embodiment. The rack-mounted UPS system 100 according to the third embodiment is essentially depicted to show details of internal power distribution bus 120. Hence, features of the third embodiment, which are not discussed in detail, correspond to the respective features of the first and/or second embodiment.

The power distribution bus 120 comprises parallel vertical bus bars 124 running through the UPS rack 112 to allow electrical connection of an enclosure 110, 122 at any insertion slot. The bus bars 124 are provided in a rear part of the UPS rack 112. Some of the vertical bus bars 124 extend through the entire height of the UPS rack 112, as can be seen in the left rack-mounted UPS device 102 of FIG. 6. Other vertical bus bars 124 extend partially through the UPS rack 112, as can be seen in the right rack-mounted UPS device 102 of FIG. 6. E.g., source voltages can be provided only on top of UPS rack 112, and other bus bars 124 form sets according to required load configurations. No horizontal bars are provided in this embodiment.

The different bus bars 124 implement high voltage DC bus 120 as well as internal power distribution bus 120.

FIG. 7 shows a rack-mounted UPS device 102 according to a fourth embodiment.

The rack-mounted UPS device 102 according to a fourth embodiment is in part similar to the rack-mounted UPS devices 102 of the first to third embodiments. Hence, features not discussed in detail with respect to the rack-mounted UPS device 102 of the fourth embodiment can be implemented as discussed with respect to any of the first to third embodiments. Furthermore, features not discussed in detail with respect to the first to third embodiments can be implemented as discussed in detail with respect to the rack-mounted UPS device 102 of the fourth embodiment.

The rack-mounted UPS devices 102 comprises a UPS rack 112, one primary converter 104, one secondary converter 106, and one load supply converter 108, as discussed above with respect e.g. to the first embodiment. The primary converter 104, the secondary converter 106, and the load supply converter 108 are electrically interconnected through a high voltage DC bus 114. The primary converter 104, the secondary converter 106, and the load supply converter 108 are arranged together with the high voltage DC bus 114 in one converter enclosure 110 for insertion into a slot of the UPS rack 112.

The high voltage DC bus 114 has a voltage of more than 200V in this embodiment. In an alternative embodiment, the high voltage DC bus 114 has a voltage of more than 300V. The primary converter 104 and the secondary converter 106 are both configured to operate in boost mode providing high voltage DC power output to the high voltage DC bus 114.

The primary converter 104 of the converter enclosure 110 is electrically connected to an AC source 118. The secondary converter 106 is connected to a DC source 138, which is provided as a battery. The battery 138 is according to the fourth embodiment mounted in the UPS rack 112. In an alternative embodiment, the battery 138 is provided out of the UPS rack 112, e.g. in a battery cabinet. The battery 138 is chargeable via the secondary converter 106 from the high voltage DC bus 114.

The rack-mounted UPS device 102 comprises an internal power distribution bus 120, which is connected to the load supply converter 108, which provides different low level DC output voltages to the internal power distribution bus 120.

As can be seen in FIG. 7, the load supply converter 108 is provided as a converter block comprising multiple converter units 140, each of which providing one low level DC output voltage to the internal power distribution bus 120. According to the fourth embodiment, the multiple converter units 140 provide two different voltage levels load voltage 1 and load voltage 2, whereby three converter units 140 provide the identical voltage levels load voltage 1 to increase maximum current of the rack-mounted UPS device 102. Only one converter unit 140 provides load voltage 2.

The internal power distribution bus 120 distributes the low level DC output voltages within the rack-mounted UPS device 102. The power distribution bus 120 comprises parallel vertical bus bars 124 running through the UPS rack 112 to allow electrical connection of an enclosure 110, 122 at any insertion slot. Details have been discussed above with respect to the first to third embodiment. Bus bars 124 connected to identical low level DC output voltages are electrically inter-connected with a bus interconnection 142. In the fourth embodiment, the bus bars 124 connected to the converter units 140 providing load voltage 1 are interconnected by the bus interconnection 142.

The rack-mounted UPS device 102 further comprises multiple load enclosures 122 containing data processing devices, which commonly form a load 128 powered by the converters 104, 106, 108 of the rack-mounted UPS device 102. Details have been discussed above with respect to the first to third embodiment.

Furthermore, the rack-mounted UPS device 102 comprises a control unit 126 controlling operation of the primary converter 104, the secondary converter 106, and the load supply converter 108. The control unit 126 is provided within the converter enclosure 110. Details have been discussed above with respect to the first to third embodiment.

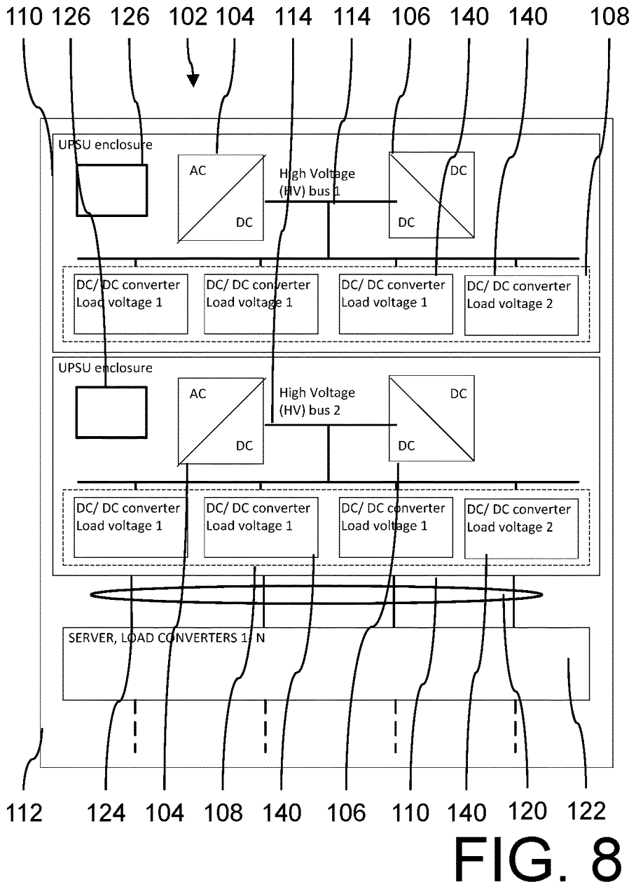

FIG. 8 shows a rack-mounted UPS device 102 according to a fifth embodiment.

The rack-mounted UPS device 102 according to a fifth embodiment is in part similar to the rack-mounted UPS device 102 of the fourth embodiment. Hence, features not discussed in detail with respect to the rack-mounted UPS device 102 of the fifth embodiment can be implemented as discussed with respect to the fourth embodiment.

The rack-mounted UPS devices 102 comprises a UPS rack 112 and two converter enclosures 110 for insertion into a slot of the UPS rack 112. Each of the converter enclosures 110 has the same structure discussed below. Hence, each converter enclosure 110 comprises one primary converter 104, one secondary converter 106, and one load supply converter 108, which are electrically interconnected through a high voltage DC bus 114. The high voltage DC buses 114 of the two converter enclosures 110 are not interconnected according to the fifth embodiment.

The primary converters 104 of both converter enclosures 110 are electrically connected to an AC source 118 not shown in FIG. 8 for the sake of simplicity. The secondary converters 106 of both converter enclosures 110 are electrically connected to a DC source 138, which not shown in FIG. 8 for the sake of simplicity. The secondary converters 106 of the fifth embodiment are connected to a common DC source 138. In an alternative embodiment, the secondary converters 106 are connected to multiple DC sources 138.

The rack-mounted UPS device 102 comprises an internal power distribution bus 120, which is connected to the load supply converter 108, which provides different low level DC output voltages to the internal power distribution bus 120. The converter enclosures 110 support in parallel the different low level DC output voltages to commonly support load 116.

Further details of the rack-mounted UPS device 102 of the fifth embodiment are as discussed above with respect to the rack-mounted UPS device 102 of the fourth embodiment.

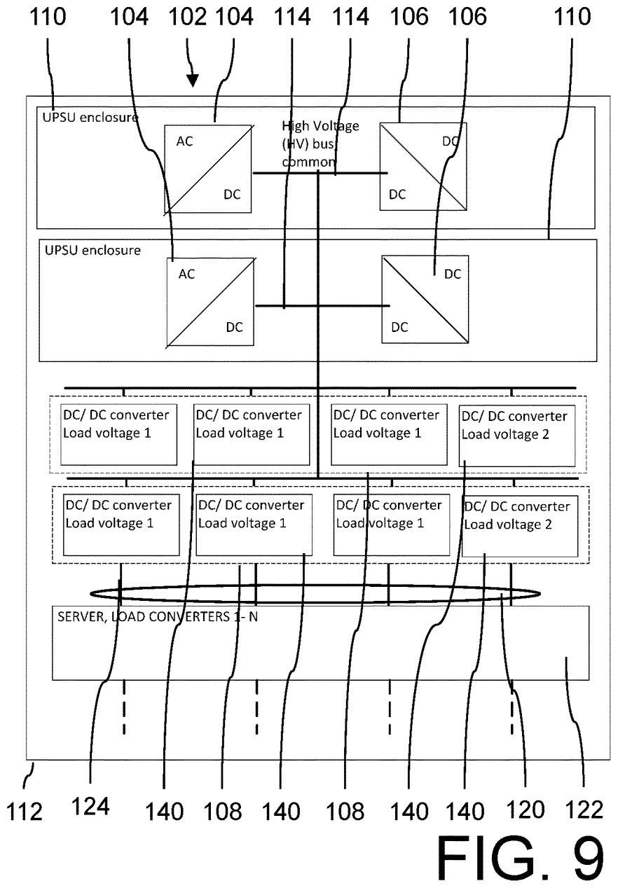

FIG. 9 shows a rack-mounted UPS device 102 according to a sixth embodiment.

The rack-mounted UPS device 102 according to a sixth embodiment is in part similar to the rack-mounted UPS device 102 of the fourth and/or fifth embodiment. Hence, features not discussed in detail with respect to the rack-mounted UPS device 102 of the sixth embodiment can be implemented as discussed with respect to the fourth and/or fifth embodiment.

The rack-mounted UPS devices 102 comprises a UPS rack 112 and two converter enclosures 110 for insertion into a slot of the UPS rack 112. The two the converter enclosures 110 have the same structure comprising a primary converter 104 and a secondary converter 106, which are electrically interconnected through a high voltage DC bus 114. The high voltage DC bus 114 is provided through the UPS rack 112.

Furthermore, the rack-mounted UPS devices 102 comprises two load supply converters 108, which are electrically connected to the high voltage DC bus 114. The load supply converters 108 are according to the sixth embodiment directly mounted in the UPS rack 112. In an alternative embodiment, the load supply converters 108 are provided in separate enclosures.

The primary converters 104 of both converter enclosures 110 are electrically connected to an AC source 118 not shown in FIG. 9 for the sake of simplicity. The secondary converters 106 of both converter enclosures 110 are electrically connected to a DC source 138, which not shown in FIG. 8 for the sake of simplicity.

The rack-mounted UPS device 102 comprises an internal power distribution bus 120. Both load supply converters 108 are connected in parallel to the internal power distribution bus 120. Both load supply converters 108 are provided as a converter block comprising multiple individual converter units 140, each of which providing one low level DC output voltage to the internal power distribution bus 120. The converter enclosures 110 support in parallel the different low level DC output voltages to commonly support load 116.

Further details of the rack-mounted UPS device 102 of the sixth embodiment are as discussed above with respect to the rack-mounted UPS device 102 of the fourth and/or fifth embodiment.

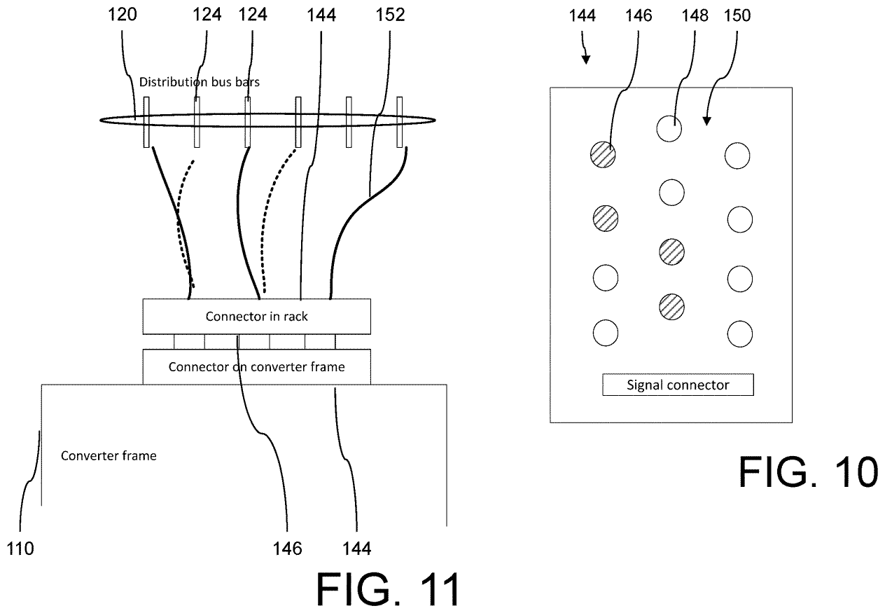

FIG. 10 refers to a signal connector 144 or plug for connection of a converter 104, 106, 108 or an enclosure 110, 122 to the internal power distribution bus 120 according to a seventh embodiment. The signal connector 144 can be provided with any of the converters 104, 106, 108 or enclosures 110, 122 of the previous embodiments for connection to a corresponding signal connector 144 connected to the internal power distribution bus 120.

The signal connector 144 comprises multiple electric pins 146, 148. Depending on requirements and/or capabilities of the respective converters 104, 106, 108 or enclosures 110, 122, the signal connector 144 comprises used or connected contact pins 146, and un-used or void contact pins 148, which are not implemented in the signal connector 144. Accordingly, an electrical interface 150 comprising used and void contact pins 146, 148 is provided. The used contact pins 146 provide respective voltage levels to the converters 104, 106, 108 and/or enclosures 110, 122. The signal connector 144 is provided as plug according to the seventh embodiment. According to an alternative embodiment, the signal connector 144 is provided as socket.

FIG. 11 shows by way of example a plug connection established between a converter enclosure 110 and the internal power distribution bus 120 according to an eighth embodiment. The converter enclosure 110 is provided with a signal connector 144 according to the seventh embodiment. A further signal connector 144, which corresponds to the signal connector 144 of the converter enclosure 110, is connected via cables 152 to the internal power distribution bus 120. The two signal connectors 144 are provided as a mating pair of plug and socket.

While the invention has been illustrated and described in detail in the drawings and foregoing description, such illustration and description are to be considered illustrative or exemplary and not restrictive; the invention is not limited to the disclosed embodiments. Other variations to be disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting scope.

### REFERENCE SIGNS LIST

10 UPS system (state of the art)
12 UPS-rack (state of the art)
14 converter (state of the art)
16 AC/DC converter (state of the art)
18 DC/AC converter (state of the art)
20 DC/DC converter (state of the art)
22 AC source (state of the art)
24 DC link (state of the art)
26 AC power distribution bus (state of the art)
28 battery (state of the art)
30 battery cabinet (state of the art)
32 control device (state of the art)
34 load (state of the art)
36 load rack (state of the art)
38 enclosure (state of the art)
40 load device (state of the art)
42 power supply unit, PSU (state of the art)
44 AC/DC converter (state of the art)
46 DC/DC converter (state of the art)
48 system communication bus (state of the art)
50 user interface (state of the art)
100 rack-mounted UPS system
102 rack-mounted UPS device
104 primary converter, AC/DC converter
106 secondary converter, DC/DC converter
108 load supply converter
110 converter enclosure
112 UPS rack
114 high voltage DC bus
116 load
118 AC source
120 internal power distribution bus
122 load enclosure
124 bus bar, bus connection
126 control unit
128 user interface
130 inter-rack communication bus
132 control device
134 external power distribution bus
136 protection and/or disconnect device
138 DC source, battery
140 converter unit
142 bus interconnection
144 signal connector
146 contact pin (used)
148 contact pin (void)
150 electrical interface
152 cable

1. A rack-mounted UPS device for power supply of a load comprising multiple data processing devices, which can be inserted as load enclosures into a common UPS rack, the rack-mounted UPS device comprising
at least one primary converter, which is connected between an AC source and a high voltage DC bus, whereby the primary converter is configured to operate in boost mode providing high voltage DC power output to the high voltage DC bus,
at least one secondary converter, which is connected between a DC source and the high voltage DC bus, whereby the secondary converter is configured to operate in boost mode providing high voltage DC power output to the high voltage DC bus,
at least one load supply converter, which is connected between the high voltage DC bus and an internal power distribution bus to provide at least one low level DC output voltage to the internal power distribution bus, whereby
the at least one primary converter, the at least one secondary converter, and the at least one load supply converter are mounted in the UPS rack,
the UPS rack comprises multiple insertion slots for receiving the load enclosures comprising the data processing devices, and
the internal power distribution bus is provided for distribution of the load voltages between the enclosures.

2. The rack-mounted UPS device according to claim 1, wherein
the load supply converter is provided as a converter block comprising multiple converter units, each of which providing at least one low level DC output voltage to the internal power distribution bus.

3. The rack-mounted UPS device according to claim 1, wherein
the DC source comprises at least one energy storage device.

4. The rack-mounted UPS device according to claim 1, wherein
the DC source comprises at least one uni-directional source out of a photovoltaic source, a fuel cell, or a rotary or inertia generator.

5. The rack-mounted UPS device according to claim 3, wherein
the DC source comprises multiple energy storage devices and/or uni-directional sources, and
the rack-mounted UPS device comprises multiple secondary converters, whereby the multiple secondary converters are connected in parallel between the multiple energy storage units and the high voltage DC bus.

6. The rack-mounted UPS device according to claim 1, wherein
the at least one primary converter the at least one secondary converter, and the at least one load supply converter are arranged at least partially in at least one converter enclosure for insertion into a slot of the UPS rack, whereby the at least one primary converter, the at least one secondary converter, and the at least one load supply converter are electrically interconnected through the internal power distribution bus.

7. The rack-mounted UPS device according to claim 6, wherein
one primary converter, one secondary converter, and one load supply converter are mounted in a common converter enclosure, which is mounted in the UPS rack.

8. The rack-mounted UPS device according to claim 6, wherein
the at least one primary converter and the at least one secondary converter are arranged in at least one converter enclosure for insertion into a slot of the UPS rack, and
the at least one load supply converter is arranged in at least one converter enclosure for insertion into an insertion slot of the UPS rack, whereby the converter enclosures are electrically interconnected through the internal power distribution bus.

9. The rack-mounted UPS device according to claim 1, wherein
the internal power distribution bus includes multiple parallel bus connections for at least one voltage level, and
the multiple parallel bus connections for one voltage level are electrically connected with at least one bus interconnection.

10. The rack-mounted UPS device according to claim 1, wherein
at least one of the at least one primary converter, the at least one secondary converter, and the at least one load supply converter has an electrical interface for connection to the internal power distribution bus with at least one out of a set of standardized electrical configurations.

11. The rack-mounted UPS device according to claim 1, wherein
the rack-mounted UPS device comprises at least one control unit controlling operation of the at least one primary converter, the at least one secondary converter, and the at least one load supply converter.

12. The rack-mounted UPS device according to claim 11, wherein
the rack-mounted UPS device comprises a user interface for interaction of the at least one control unit controlling operation of the at least one primary converter, the at least one secondary converter, and the at least one load supply converter.

13. The rack-mounted UPS device according to claim 1, wherein
the internal power distribution bus comprises parallel vertical bus bars running through the UPS rack to allow electrical connection of an enclosure at any insertion slot.

14. A rack-mounted UPS system for power supply of a load comprising multiple data processing devices, comprising multiple rack-mounted UPS devices according to claim 1, wherein the rack-mounted UPS system comprises an inter-rack communication bus for commonly controlling the at least one primary converter, the at least one secondary converter, and the at least one load supply converter of the multiple rack-mounted UPS devices.

15. The rack-mounted UPS system according to claim 14, wherein
the multiple rack-mounted UPS devices are connected electrically in parallel by an external power distribution bus.

16. The rack-mounted UPS system according to claim 15, wherein
the rack-mounted UPS system comprises multiple protection and/or disconnect devices, which connect the multiple rack-mounted UPS devices to the external power distribution bus.

17. The rack-mounted UPS device according to, claim 2, wherein the DC source comprises at least one energy storage device, in particular a battery, e.g. lead acid battery, a VRLA battery, or others, or ultracapacitors.

18. The rack-mounted UPS device according to, claim 3, wherein the at least one energy storage device is one of a battery, e.g. lead acid battery, a VRLA battery, or ultracapacitors.

19. The rack-mounted UPS device according to claim 4, wherein the at least one uni-directional source out of a photovoltaic source, a fuel cell, or a rotary or inertia generator is one of a wind mill, a turbine, or a fly wheel.

20. The rack-mounted UPS device according to claim 4, wherein the DC source comprises multiple energy storage devices and/or uni-directional sources, and
the rack-mounted UPS device comprises multiple secondary converters, whereby the multiple secondary converters are connected in parallel between the multiple energy storage units and the high voltage DC bus.
